(19) United States
(12) Patent Application Publication
(10) Pub. No.: US 2025/0132156 A1
(43) Pub. Date: Apr. 24, 2025

(54) NARROW LINE CUT MASKING PROCESS

(71) Applicant: Geminatio, Inc., Schenectady, NY (US)

(72) Inventors: Brennan Peterson, Longmont, CO (US); Phillip D. Hustad, Longmont, CO (US)

(73) Assignee: Geminatio, Inc., Schenectady, NY (US)

(21) Appl. No.: 18/686,838

(22) PCT Filed: Aug. 25, 2022
(86) PCT No.: PCT/US2022/041545

§ 371 Date: Feb. 26, 2024

Related U.S. Application Data
(60) Provisional application No. 63/236,803, filed on Aug. 25, 2021.
(60) Provisional application No. 63/236,855, filed on Aug. 25, 2021.

(51) Int. Cl. H01L 21/027; G03F 7/32; H01L 21/308

(52) U.S. Cl. CPC H01L 21/027; G03F 7/327; H01L 21/308

(57) ABSTRACT

A method of patterning a substrate includes providing a first relief pattern on a substrate, wherein the first relief pattern includes a first resist, coating the first relief pattern with a solubility-shifting agent, depositing a second resist on the first relief pattern such that the second resist is in contact with the first relief pattern, and diffusing the solubility-shifting agent a predetermined distance into the second resist to provide a solubility-shifted region of the second resist. The solubility-shifted region of the second resist borders the first relief pattern. Then, the method includes developing the second resist such that the solubility-shifted region is dissolved providing gaps between the first relief pattern and the second resist where a portion of the substrate is exposed and etching the substrate using the first relief pattern and the second resist as a combined etch mask.

### CROSS REFERENCE TO RELATED APPLICATIONS

This application is a national stage application claiming priority to International Application Serial No. PCT/US2022/041545, entitled Narrow Cut Line Masking Process, filed Aug. 25, 2023, hereby incorporated herein by reference.

### BACKGROUND

Microfabrication of semiconductor devices includes various steps such as film deposition, pattern formation, and pattern transfer. Materials and films are deposited on a substrate by spin coating, vapor deposition, and other deposition processes. Pattern formation is typically performed by exposing a photo-sensitive film, known as a photoresist, to a pattern of actinic radiation typically using a KrF excimer laser at 248 nm, ArF excimer laser at 193 nm, or an extreme ultraviolet (EUV) exposure tool at 13.5 nm, and subsequently developing the photoresist to form a relief pattern. The relief pattern then acts as an etch mask, which, when one or more etching processes are applied to the substrate, cover portions of the substrate that are not to be etched. Line cuts are normally achieved on a substrate using such photolithography steps, where each cut is placed individually with a separate lithography exposure. This is challenging as line widths decrease, especially when cuts are to be placed near each other.

Typically, before pattern formation, a pattern is first etched onto one or more transfer layers, for example, a hard mask layer or a bottom antireflective coating (BARC) layer, and then transferred to the substrate layer. Thus, current microfabrication techniques require many steps, and are often very expensive to perform.

### SUMMARY

This summary is provided to introduce a selection of concepts that are further described below in the detailed description. This summary is not intended to identify key or essential features of the claimed subject matter, nor is it intended to be used as an aid in limiting the scope of the claimed subject matter.

In one aspect, embodiments disclosed herein relate to a method of patterning a substrate including providing a first relief pattern on a substrate, wherein the first relief pattern includes a first resist, coating the first relief pattern with a solubility-shifting agent, depositing a second resist on the first relief pattern such that the second resist is in contact with the first relief pattern, and diffusing the solubility-shifting agent a predetermined distance into the second resist to provide a solubility-shifted region of the second resist, wherein the solubility-shifted region of the second resist borders the first relief pattern. Then, the method includes developing the second resist such that the solubility-shifted region is dissolved providing gaps between the first relief pattern and the second resist where a portion of the substrate is exposed, and etching the substrate using the first relief pattern and the second resist as a combined etch mask.

In another aspect, embodiments disclosed herein relate to a method of patterning a substrate including providing a first relief pattern on a substrate, wherein the first relief pattern includes a first resist, coating the first relief pattern with a solubility-shifting agent, depositing a second resist on the first relief pattern such that the second resist is in contact with the first relief pattern, and diffusing the solubility-shifting agent a predetermined distance into the first resist to provide a solubility-shifted region of the first resist, wherein the solubility-shifted region of the first resist borders the second resist. Then, the method includes developing the first resist such that the solubility-shifted region is dissolved providing gaps between the first relief pattern and the second resist where a portion of the substrate is exposed, and etching the substrate using the first relief pattern and the second resist as a combined etch mask. In yet another aspect, embodiments disclosed herein relate to a coated substrate including a first photoresist layer that includes a core polymer and a shell polymer, wherein the core polymer and the shell polymer have different solubility characteristics and a second photoresist layer coated on top of and around the first photoresist layer, wherein the second photoresist layer includes a polymer.

In one or more of the above embodiments, the first relief pattern comprises features separated by gaps between the features, wherein the features comprise the first resist.

In one or more of the above embodiments, the second resist fills the gaps of the first relief pattern.

In one or more of the above embodiments, etching the substrate comprises performing an anisotropic etch.

In one or more of the above embodiments, providing the first relief pattern on the substrate comprises: forming a first pattern of lines on the substrate; depositing a layer of the first resist over the first pattern of lines; exposing the first resist to a pattern of actinic radiation and developing the first resist such that the first relief pattern is formed over the first pattern of lines.

In one or more of the above embodiments, the solubility-shifting agent comprises an acid generator. In one or more of the above embodiments, the acid generator is free of fluorine. In one or more of the above embodiments, acid generator is selected from the group consisting of pyridinium perfluorobutane sulfonate, 3-fluoropyridinium perfluorobutanesulfonate, 4-t-butylphenyltetramethylenesulfonium perfluoro-1-butanesulfonate, 4-t-butylphenyltetramethylenesulfonium 2-trifluoromethylbenzenesulfonate, 4-t-butylphenyltetramethylenesulfonium 4,4,5,5,6,6-hexafluorodihydro-4H-1,3,2-dithiazine 1,1,3,3-tetraoxide, triphenylsulfonium antiomate, and combinations thereof.

In one or more of the above embodiments, the solubility-shifting agent comprises an acid. In one or more of the above embodiments, the acid is free of fluorine. In one or more of the above embodiments, the acid is selected from the group consisting of trifluoromethanesulfonic acid, perfluoro-1-butanesulfonic acid, p-toluenesulfonic acid, 4-dodecylbenzenesulfonic acid, 2,4-dinitrobenzenesulfonic acid, 2-trifluoromethylbenzenesulfonic acid, and combinations thereof.

In one or more of the above embodiments, the solubility-shifting agent comprises a matrix polymer comprising monomers with ethylenically unsaturated polymerizable double bonds, including (meth)acrylate monomers; (meth)acrylic acids; vinyl aromatic monomers such as styrene, hydroxystyrene, vinyl naphthalene and acenaphthylene; vinyl alcohol; vinyl chloride; vinyl pyrrolidone; vinyl pyridine; vinyl amine; vinyl acetal; maleic anhydride; maleimides; norbornenes; and combinations thereof.

In one or more of the above embodiments, the solubility-shifting agent comprises a matrix polymer comprising monomers comprising one or more functional groups chosen from hydroxy, carboxyl, sulfonic acid, sulfonamide, silanol, fluoroalcohol, anhydrates, lactones, esters, ethers, allylamine, pyrrolidones, and combinations thereof.

In one or more of the above embodiments, the method further comprises, directly after coating the first relief pattern with the solubility-shifting agent, diffusing the solubility-shifting agent into the first relief pattern.

In one or more of the above embodiments, diffusing the solubility-shifting agent into the first relief pattern is achieved by performing a bake.

In one or more of the above embodiments, the first resist is a positive tone developed resist and the second resist comprises a polymer that is soluble in a polar solvent. In one or more of the above embodiments, the first resist is a negative tone developed resist and the second resist comprises a polymer that is soluble in a nonpolar organic solvent.

In one or more of the above embodiments, the solubility-shifting agent comprises a solvent. In one or more of the above embodiments, the solvent is selected from the group consisting of methyl isobutyl carbinol (MIBC), decane, isoobutyl isobutyrate, isoamyl ether, and combinations thereof. In one or more of the above embodiments, the first resist is insoluble in the solvent. In one or more of the above embodiments, the first resist comprises a polymer made from monomers selected from the group consisting of styrene, p-hydroxystyrene, acrylate, methacrylate, norbornene, and combinations thereof.

In one or more of the above embodiments, a specific developer is a base developer. In one or more of the above embodiments, the base developer is tetramethylammonium hydroxide. In one or more of the above embodiments, a specific developer is a nonpolar organic solvent selected from the group consisting of n-butyl acetate (NBA), 2-heptanone, and combinations thereof.

In one or more of the above embodiments, the second resist comprises a polymer made from monomers selected from the group consisting of styrene, p-hydroxystyrene, acrylate, methacrylate, norbornene, and combinations thereof.

Other aspects and advantages of the claimed subject matter will be apparent from the following description and the appended claims.

### BRIEF DESCRIPTION OF DRAWINGS

FIG. 1 is a block-flow diagram of a method in accordance with one or more embodiments of the present disclosure.

FIGS. 2A-G are schematic illustrations of coated substrates at respective points of a method in accordance with one or more embodiments the present disclosure.

FIGS. 3A-F are exemplary schematic depictions of coated substrates at respective points of a method in accordance with one or more embodiments of the present disclosure. FIGS. 3G-L are corresponding top view schematic depictions.

FIGS. 4A-G are schematic illustrations of coated substrates at respective points of a method in accordance with one or more embodiments of the present disclosure.

### DETAILED DESCRIPTION

The present disclosure generally relates to a method of patterning a semiconductor substrate. In one or more embodiments, the method includes forming a controlled, narrow cut on a substrate. Herein, the terms “semiconductor substrate” and “substrate” are used interchangeably, and may be any semiconductor material including, but not limited to, semiconductor wafers, semiconductor material layers, and combinations thereof. In the present disclosure, the term “photoresist” may be used to refer to a resist material that comprises a photoacid generate and is patterned using light, whereas the term “resist” may be used to describe a resist material that is not patterned using light. It will be understood that as defined herein, narrow denotes a width of from about 5 nm to about 30 nm. Thus, methods in accordance with the present disclosure may provide cuts having a width of from about 5 nm to about 30 nm. Unlike conventional lithography patterning, methods disclosed herein achieve multiple cuts from one photolithography step, while conventional processes require multiple photolithography steps. Further, methods may include cutting a narrow line directly onto a substrate.

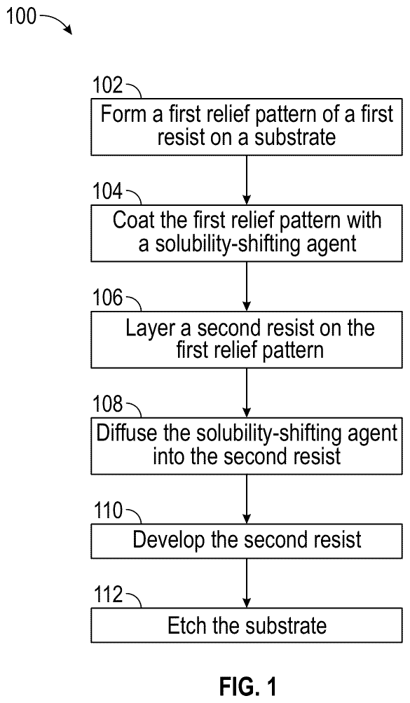

A method 100 in accordance with the present disclosure is shown in, and discussed with reference to, FIG. 1. Initially, method 100 includes, at block 102, providing a first relief pattern on a substrate. The first relief pattern may be formed using a photolithographic process and may be made of a first resist. In method 100, at block 104, the first relief pattern is coated with a solubility shifting agent. The solubility shifting agent can be a solubilizing or hardening agent, based on the polarity of the first resist. Then, at block 106, a second resist is layered on the first relief pattern, such that any exposed portion of the substrate and the first photoresist are completely covered with the second resist. At block 108, the solubility-shifting agent is then diffused into the second resist, and at block 110 the second resist is developed. Diffusion of the solubility shifting agent may form a solubility-shifted region in the second resist, that may be selectively developed, forming trenches where the substrate is exposed. After developing the second resist, the substrate may be etched, at block 112, to form a pattern of narrow cut lines formed with self-alignment of the features of the second resist.

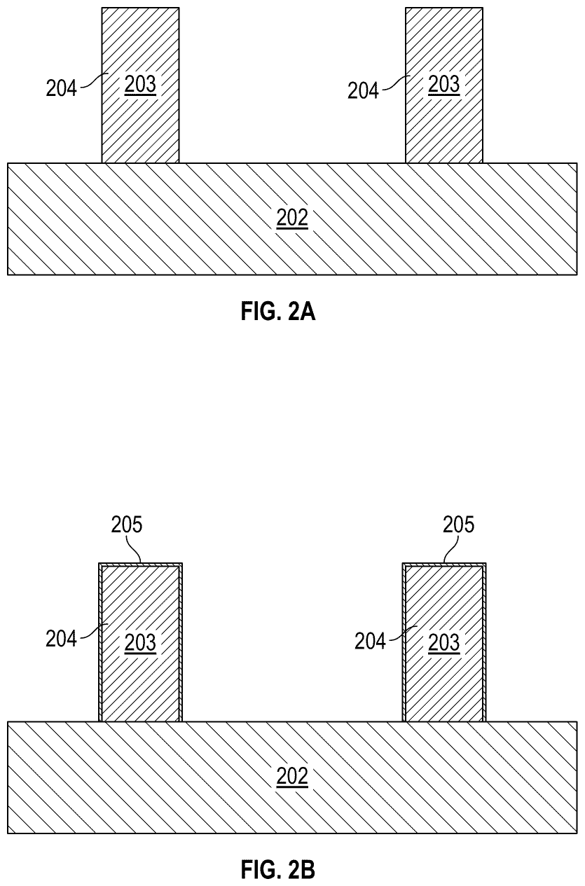

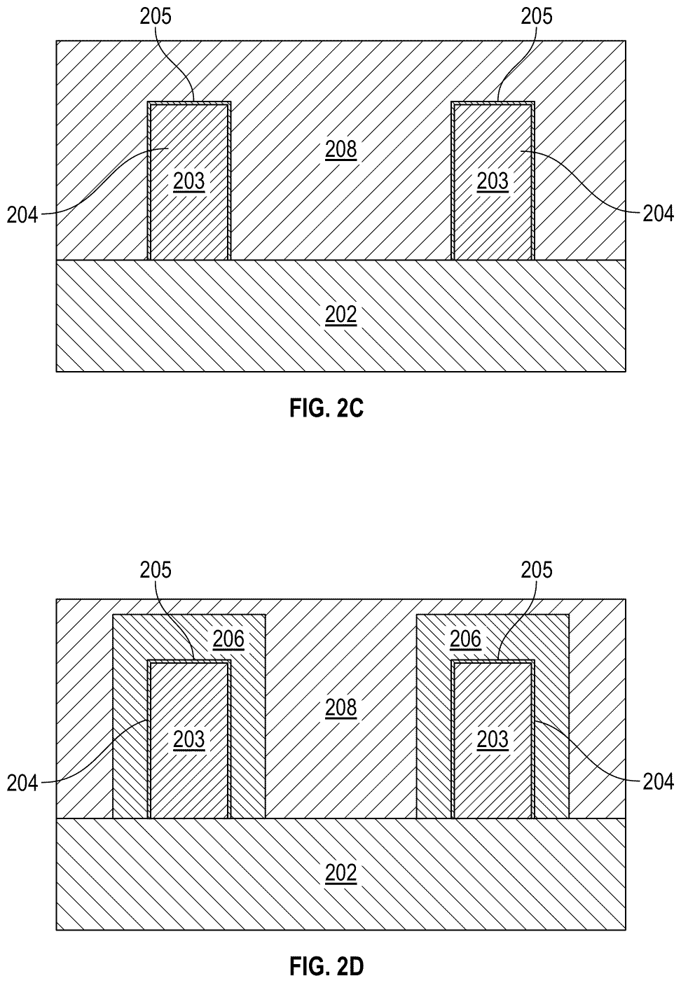

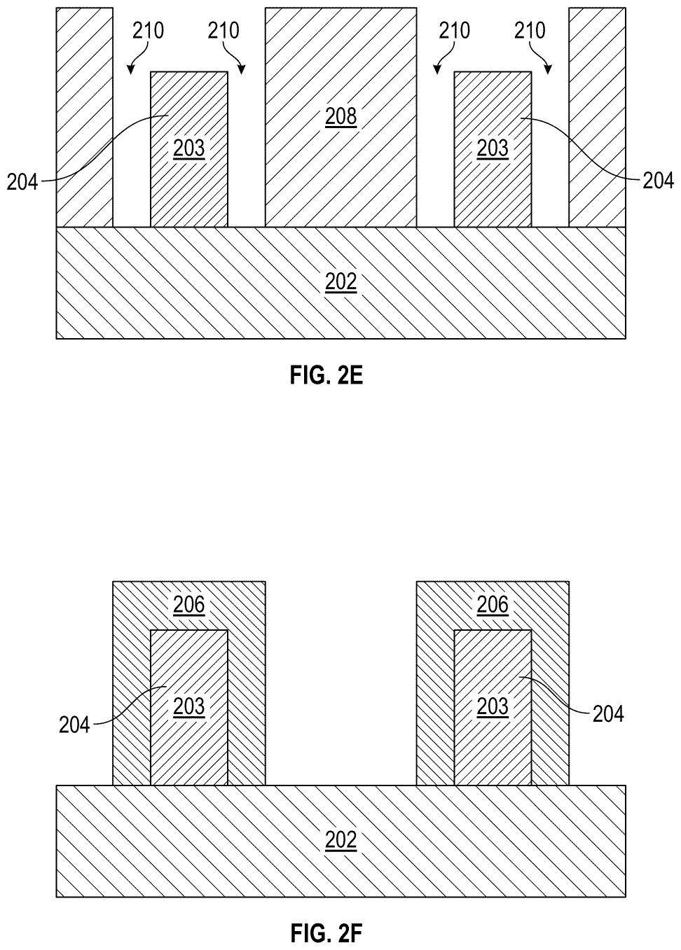

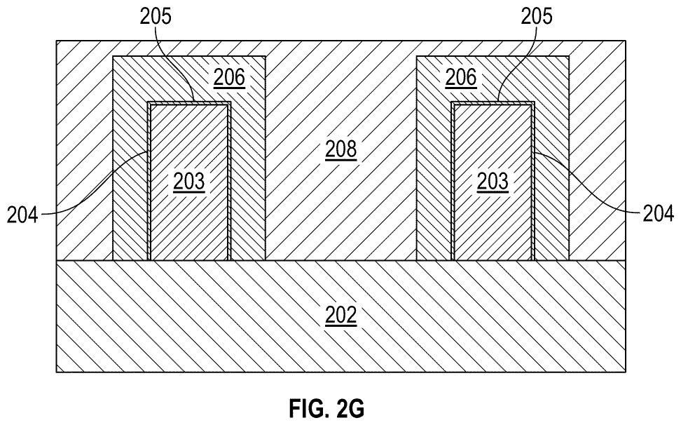

Schematic depictions of a coated substrate at various points during the method described above are shown in FIGS. 2A, 2B, 2C, 2D, 2E. Herein “a coated substrate” refers to a substrate that is coated with one or more layers, such as a first photoresist layer and a second resist layer. FIG. 2A shows a substrate including a first relief pattern. FIG. 2B shows a substrate including a first relief pattern coated with a solubility-shifting agent. In FIG. 2C, a second resist is layered over the substrate and the first relief pattern. FIG. 2D shows a coated substrate after the solubility-shifting agent has been diffused into the second resist. Finally, FIG. 2E shows a coated substrate after the second resist has been developed, such that portions of the substrate are exposed and able to be etched. The method of FIG. 1 and coated substrates shown in FIGS. 2A-2E are discussed in detail below.

At block 102 of method 100, a first relief pattern is provided. FIG. 2A shows an example of a first relief pattern 204 on a substrate 202. A shown in FIG. 2A, the first relief pattern may include features separated by gaps. Portions of the substrate may be exposed by the presence of the gaps of the first relief pattern. The features of the first relief pattern may be made of a first resist 203. The first resist may be a photoresist. Generally, a photoresist is a chemically amplified photosensitive composition that comprises a polymer, a photoacid generator, and a solvent. In one or more embodiments, the first resist includes a polymer. The polymer may be any standard polymer typically used in photoresist material and may particularly be a polymer having acid-labile groups. For example, the polymer may be a polymer made from monomers including vinyl aromatic monomers such as styrene and p-hydroxystyrene, acrylate, methacrylate, norbornene, and combinations thereof. Monomers that include reactive functional groups may be present in the polymer in a protected form. For example, the —OH group of p-hydroxystyrene may be protected with a tert-butyloxycarbonyl protecting group. Such protecting group may alter the reactivity and solubility of the polymer included in the first photoresist. As will be appreciated by one having ordinary skill in the art, various protecting groups may be used for this reason. Acid-labile groups include, for example: tertiary alkyl ester groups, secondary or tertiary aryl ester groups, secondary or tertiary ester groups having a combination of alkyl and aryl groups, tertiary alkoxy groups, acetal groups, or ketal groups. Acid-labile groups are also commonly referred to in the art as “acid-decomposable groups”, “acid-cleavable groups,” “acid-cleavable protecting groups,” “acid-labile protecting groups,” “acid-leaving groups,” and “acid-sensitive groups.”

The acid-labile group which, on decomposition, forms a carboxylic acid on the polymer is preferably a tertiary ester group of the formula —C(O)OC(R¹)₃ or an acetal group of the formula —C(O)OC(R²)₂OR³, wherein: R¹ is each independently linear C₁₋₂₀ alkyl, branched C₃₋₂₀ alkyl, monocyclic or polycyclic C₃₋₂₀ cycloalkyl, linear C₂₋₂₀ alkenyl, branched C₃₋₂₀ alkenyl, monocyclic or polycyclic C₃₋₂₀ cycloalkenyl, monocyclic or polycyclic C₆₋₂₀ aryl, or monocyclic or polycyclic C₂₋₂₀ heteroaryl, preferably linear C₁₋₆ alkyl, branched C₃₋₆ alkyl, or monocyclic or polycyclic C₃₋₁₀ cycloalkyl, each of which is substituted or unsubstituted, each R¹ optionally including as part of its structure one or more groups chosen from —O—, —C(O)—, —C(O)—O—, or —S—, and any two R¹ groups together optionally forming a ring; R² is independently hydrogen, fluorine, linear C₁₋₂₀ alkyl, branched C₃₋₂₀ alkyl, monocyclic or polycyclic C₃₋₂₀ cycloalkyl, linear C₂₋₂₀ alkenyl, branched C₃₋₂₀ alkenyl, monocyclic or polycyclic C₃₋₂₀ cycloalkenyl, monocyclic or polycyclic C₆₋₂₀ aryl, or monocyclic or polycyclic C₂₋₂₀ heteroaryl, preferably hydrogen, linear C₁₋₆ alkyl, branched C₃₋₆ alkyl, or monocyclic or polycyclic C₃₋₁₀ cycloalkyl, each of which is substituted or unsubstituted, each R² optionally including as part of its structure one or more groups chosen from —O—, —C(O)—, —C(O)—O—, or —S—, and the R² groups together optionally forming a ring; and R³ is linear C₁₋₂₀ alkyl, branched C₃₋₂₀ alkyl, monocyclic or polycyclic C₃₋₂₀ cycloalkyl, linear C₂₋₂₀ alkenyl, branched C₃₋₂₀ alkenyl, monocyclic or polycyclic C₃₋₂₀ cycloalkenyl, monocyclic or polycyclic C₆₋₂₀ aryl, or monocyclic or polycyclic C₂₋₂₀ heteroaryl, preferably linear C₁₋₆ alkyl, branched C₃₋₆ alkyl, or monocyclic or polycyclic C₃₋₁₀ cycloalkyl, each of which is substituted or unsubstituted, R³ optionally including as part of its structure one or more groups chosen from —O—, —C(O)—, —C(O)—O—, or —S—, and one R² together with R³ optionally forming a ring. Such monomer is typically a vinyl aromatic, (meth)acrylate, or norbornyl monomer. The total content of polymerized units comprising an acid-decomposable group which forms a carboxylic acid group on the polymer is typically from 10 to 100 mole %, more typically from 10 to 90 mole % or from 30 to 70 mole %, based on total polymerized units of the polymer.

The polymer can further include as polymerized a monomer comprising an acid-labile group, the decomposition of which group forms an alcohol group or a fluoroalcohol group on the polymer. Suitable such groups include, for example, an acetal group of the formula —COC(R²)₂OR³—, or a carbonate ester group of the formula —OC(O)O—, wherein R is as defined above. Such monomer is typically a vinyl aromatic, (meth)acrylate, or norbornyl monomer. If present in the polymer, the total content of polymerized units comprising an acid-decomposable group, the decomposition of which group forms an alcohol group or a fluoroalcohol group on the polymer, is typically from 10 to 90 mole %, more typically from 30 to 70 mole %, based on total polymerized units of the polymer.

In embodiments in which the first resist is a photoresist, the first resist includes a photoacid generator. The photoacid generator is a compound capable of generating an acid upon irradiation with actinic rays or radiation. The photoacid generator may be selected from known compounds capable of generating an acid upon irradiation with actinic rays or radiation which are used for a photoinitiator for cationic photopolymerization, a photoinitiator for radical photopolymerization, a photodecoloring agent for dyes, a photodiscoloring agent, a microresist, or the like, and a mixture thereof can be used. Examples of the photoacid generator include a diazonium salt, a phosphonium salt, a sulfonium salt, an iodonium salt, imidosulfonate, oxime sulfonate, diazodisulfone, disulfone, and o-nitrobenzyl sulfonate.

Suitable photoacids include onium salts, for example, triphenylsulfonium trifhioromethanesulfonate, (p-tert-butoxyphenyl)diphenylsulfonium tris(p-tert-butoxyphenyl) sulfonium trifhioromethanesulfonate, trifluoromethanesulfonate, triphenylsulfonium p-toluenesulfonate; di-t-butyphenyliodonium perfluorobutanesulfonate, and di-t-butyphenyliodonium camphorsulfonate. Non-ionic sulfonates and sulfonyl compounds are also known to function as photoacid generators, e.g., nitrobenzyl derivatives, for example, 2-nitrobenzyl-p-toluenesulfonate, 2,6-dinitrobenzyl-p-toluenesulfonate, and 2,4-dinitrobenzyl-p-toluenesulfonate; sulfonic acid esters, for example, 1,2,3-tris(methanesulfonyloxy)benzene, 1,2,3-tris(trifluoromethanesulfonyloxy)benzene, and 1,2,3-tris(p-toluenesulfonyloxy)benzene; diazomethane derivatives, for example, bis(benzenesulfonyl)diazomethane, bis(p-toluenesulfonyl)diazomethane; glyoxime derivatives, for example, bis-O-(p-toluenesulfonyl)-α-dimethylglyoxime, and bis-O-(n-butanesulfonyl)-α-dimethylglyoxime; sulfonic acid ester derivatives of an N-hydroxyimide compound, for example, N-hydroxysuccinimide methanesulfonic acid ester, N-hydroxysuccinimide trifluoromethanesulfonic acid ester; and halogen-containing triazine compounds, for example, 2-(4-methoxyphenyl)-4,6-bis(trichloromethyl)-1,3,5-triazine, and 2-(4-methoxynaphthyl)-4,6-bis(trichloromethyl)-1,3,5-triazine. Suitable non-polymerized photoacid generators are further described in U.S. Pat. No. 8,431,325 to Hashimoto et al. in column 37, lines 11-47 and columns 41-91. Other suitable sulfonate PAGs include sulfonated esters and sulfonyloxy ketones, nitrobenzyl esters, s-triazine derivatives, benzoin tosylate, t-butylphenyl α-(p-toluenesulfonyloxy)-acetate, and t-butyl α-(p-toluenesulfonyloxy)-acetate; as described in U.S. Pat. Nos. 4,189,323 and 8,431,325. PAGs that are onium salts typically comprise an anion having a sulfonate group or a non-sulfonate type group, such as a sulfonamidate group, a sulfonimidate group, a methide group, or a borate group.

The resist composition may optionally comprise a plurality of PAGs. The plural PAGs may be polymeric, non-polymeric, or may include both polymeric and non-polymeric PAGs. Preferably, each of the plurality of PAGs is non-polymeric. Preferably, when a plurality of PAGs are used, a first PAG comprises a sulfonate group on the anion and a second PAG comprises an anion that is free of sulfonate groups, such anion containing for example, a sulfonamidate group, a sulfonimidate group, a methide group, or a borate group such as described above.

The first relief pattern may be formed by layering the first resist onto a substrate and the developing the first resist. The first resist may be developed according to procedures known in the art, e.g., exposure to actinic radiation followed by rinsing with a first photoresist developer. In order to impart a shape, or relief pattern, in the developed resist, a mask may be used to block a portion of the resist from the actinic radiation. After the actinic radiation is applied, the unexposed portion of the resist may have a different solubility than the exposed portion of the resist. Subsequent rinsing with the first resist developer will dissolve either the unexposed portion or the exposed portion. A relief pattern provided when the unexposed portion of the resist remains after rinsing with a developer is a positive tone developed resist. In contrast, a relief pattern provided when the exposed portion of the resist remains after rinsing with a developer is a negative tone developed resist.

In some embodiments, the first resist is a positive tone developed (PTD) resist. In such embodiments, the first relief pattern may include a polymer made from the above described monomers, wherein any monomers including a reactive functional group are protected. As such, a PTD first resist may be organic soluble, and thus the relief pattern may be provided by rinsing with a first resist developer that is basic. Suitable basic first resist developers include quaternary ammonium hydroxides, such as tetramethylammonium hydroxide (TMAH).

In other embodiments, the first resist is a negative resist. In such embodiments, the first relief pattern may include a polymer made from the above described monomers, wherein any monomers including a reactive functional group are not protected. Exposure to actinic radiation results in crosslinking of the polymer in areas of exposure, rendering the polymer insoluble to developers. The unexposed and thus uncrosslinked areas can then be removed using an appropriate developer to form the relief pattern.

In other embodiments, the first resist is a negative tone developed (NTD) resist. Similar to PTD resists, NTD resists may include a polymer made from the above described monomers, wherein any monomers including a reactive functional group are protected. As such, a NTD first resist may be organic soluble, but instead of developing the exposed areas with a first resist developer that is basic, the first relief pattern may be provided by rinsing the first resist with a first resist developer including an organic solvent. Suitable organic solvents that may be used as a first resist developer include n-butyl acetate (NBA) and 2-heptanone. The tone of the resist (i.e., PTD vs. negative vs. NTD) may influence the subsequent chemistry applied to the first relief pattern.

In other embodiments, the first resist optionally contains other additives, wherein other additives include at least one of a resin having at least either a fluorine atom or a silicon atom, a basic compound, a surfactant, an onium carboxylate, dye, a plasticizer, a photosensitizer, a light absorbent, an alkali-soluble resin, a dissolution inhibitor, and a compound for accelerating dissolution in a developer.

As previously described, the first relief pattern may include features separated by gaps. In one or more embodiments, the features of the first relief pattern may have a thickness of about 300 to 3000 Å. The gaps separating the features may leave portions of the substrate exposed.

In some embodiments, the first relief pattern is stabilized prior to coating with the solubility-shifting agent. Various resist stabilization techniques, also known as freeze processes, have been proposed such as ion implantation, UV curing, thermal hardening, thermal curing and chemical curing. Techniques are described, for example, in US2008/0063985A1, US 2008/0199814A1 and US 2010/0330503A1.

At block 104 of method 100, the first relief pattern is coated with a solubility-shifting agent. A coated substrate in accordance with block 104 is shown in FIG. 2B. The solubility-shifting agent 205 is shown as a thin coating over the first relief pattern 204. The thickness of the solubility-shifting agent coating is not particularly limited and may be altered based on the desired line cut width. The solubility-shifting agent may be a material that is absorbed into the first photoresist via a bake, and in some instances herein may be referred to as an “absorbed material.” The process of absorbing the solubility-shifting agent into the first photoresist is described in detailed below.

The composition of the solubility-shifting agent may depend on the tone of the first photoresist. Generally, the solubility-shifting agent may be any chemical that activates with light or heat. For example, when the first photoresist is a PTD photoresist, the solubility-shifting agent may include an acid or thermal acid generator. The acid or generated acid in the case of a TAG should be sufficient with heat to cause cleavage of the bonds of acid-decomposable groups of the polymer in a surface region of the first photoresist pattern to cause increased solubility of the first photoresist polymer in a specific developer to be applied. The acid or TAG is typically present in the composition in an amount of from about 0.01 to 20 wt % based on the total solids of the solubility-shifting agent.

Preferable acids are organic acids including non-aromatic acids and aromatic acids, each of which can optionally have fluorine substitution. Suitable organic acids include, for example: carboxylic acids such as alkanoic acids, including formic acid, acetic acid, propionic acid, butyric acid, dichloroacetic acid, trichloroacetic acid, perfluoroacetic acid, perfluorooctanoic acid, oxalic acid malonic acid and succinic acid; hydroxyalkanoic acids, such as citric acid; aromatic carboxylic acids such as benzoic acid, fluorobenzoic acid, hydroxybenzoic acid and naphthoic acid; organic phosphorus acids such as dimethylphosphoric acid and dimethylphosphinic acid; and sulfonic acids such as optionally fluorinated alkylsulfonic acids including methanesulfonic acid, trifluoromethanesulfonic acid, ethanesulfonic acid, 1-butanesulfonic acid, 1-perfluorobutanesulfonic acid, 1,1,2,2-tetrafluorobutane-1-sulfonic acid, 1,1,2,2-tetrafluoro-4-hydroxybutane-1-sulfonic acid, 1-pentanesulfonic acid, 1-hexanesulfonic acid, and 1-heptanesulfonic acid.

Exemplary aromatic acids that are free of fluorine include wherein aromatic acids of the general formula (I):

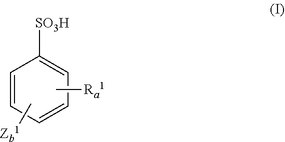

wherein: R1 independently represents a substituted or unsubstituted C1-C20 alkyl group, a substituted or unsubstituted C5-C20 aryl group or a combination thereof, optionally containing one or more group chosen from carbonyl, carbonyloxy, sulfonamido, ether, thioether, a substituted or unsubstituted alkylene group, or a combination thereof; Z1 independently represents a group chosen from carboxyl, hydroxy, nitro, cyano, C1 to C5 alkoxy, formyl and sulfonic acid; a and b are independently an integer from 0 to 5; and a+b is 5 or less.

Exemplary aromatic acids may be of the general formula (II):

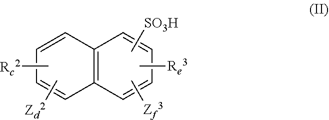

wherein: R2 and R3 each independently represents a substituted or unsubstituted C1-C20 alkyl group, a substituted or unsubstituted C5-C16 aryl group or a combination thereof, optionally containing one or more group chosen from carbonyl, carbonyloxy, sulfonamido, ether, thioether, a substituted or unsubstituted alkylene group, or a combination thereof; Z2 and Z3 each independently represents a group chosen from carboxyl, hydroxy, nitro, cyano, C₁ to C₅ alkoxy, formyl and sulfonic acid; c and d are independently an integer from 0 to 4; c+d is 4 or less; e and f are independently an integer from 0 to 3; and e+f is 3 or less.

Additional aromatic acids that may be included in the solubility-shifting agent include those the general formula (III) or (IV):

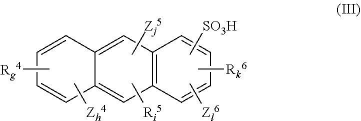

wherein: R4, R5 and R6 each independently represents a substituted or unsubstituted C1-C20 alkyl group, a substituted or unsubstituted C5-C12 aryl group or a combination thereof, optionally containing one or more group chosen from carbonyl, carbonyloxy, sulfonamido, ether, thioether, a substituted or unsubstituted alkylene group, or a combination thereof; Z4, Z5 and Z6 each independently represents a group chosen from carboxyl, hydroxy, nitro, cyano, C1 to C5 alkoxy, formyl and sulfonic acid; g and h are independently an integer from 0 to 4; g+h is 4 or less; i and j are independently an integer from 0 to 2; i+j is 2 or less; k and 1 are independently an integer from 0 to 3; and k+1 is 3 or less;

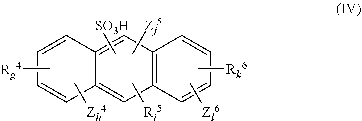

wherein: R4, R5 and R6 each independently represents a substituted or unsubstituted C1-C20 alkyl group, a substituted or unsubstituted C5-C12 aryl group or a combination thereof, optionally containing one or more group chosen from carbonyl, carbonyloxy, sulfonamido, ether, thioether, a substituted or unsubstituted alkylene group, or a combination thereof; Z4, Z5 and Z6 each independently represents a group chosen from carboxyl, hydroxy, nitro, cyano, C1 to C5 alkoxy, formyl and sulfonic acid; g and h are independently an integer from 0 to 4; g+h is 4 or less; i and j are independently an integer from 0 to 1; i+j is 1 or less; k and l are independently an integer from 0 to 4; and k+1 is 4 or less.

Suitable aromatic acids may alternatively be of the general formula (V):

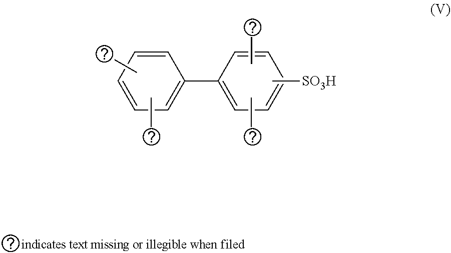

wherein: R7 and R8 each independently represents a substituted or unsubstituted C1-C20 alkyl group, a substituted or unsubstituted C5-C14 aryl group or a combination thereof, optionally containing one or more group chosen from carboxyl, carbonyl, carbonyloxy, sulfonamido, ether, thioether, a substituted or unsubstituted alkylene group, or a combination thereof; Z7 and Z8 each independently represents a group chosen from hydroxy, nitro, cyano, C1 to C5 alkoxy, formyl and sulfonic acid; m and n are independently an integer from 0 to 5; m+n is 5 or less; o and p are independently an integer from 0 to 4; and o+p is 4 or less.

Additionally, exemplary aromatic acids may have the general formula (VI):

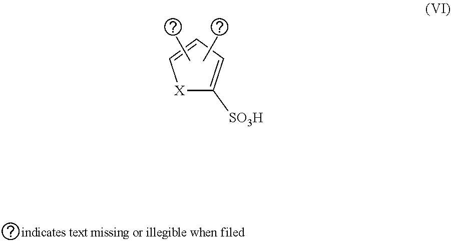

wherein: X is O or S; R9 independently represents a substituted or unsubstituted C1-C20 alkyl group, a substituted or unsubstituted C5-C20 aryl group or a combination thereof, optionally containing one or more group chosen from carbonyl, carbonyloxy, sulfonamido, ether, thioether, a substituted or unsubstituted alkylene group, or a combination thereof; Z9 independently represents a group chosen from carboxyl, hydroxy, nitro, cyano, C1 to C5 alkoxy, formyl and sulfonic acid; q and r are independently an integer from 0 to 3; and q+r is 3 or less.

In one or more embodiments, the acid is a free acid having fluorine substitution. Suitable free acids having fluorine substitution may be aromatic or nonaromatic. For example, free acid having fluorine substitution that may be used as solubility-shifting agent include, but are not limited to the following:

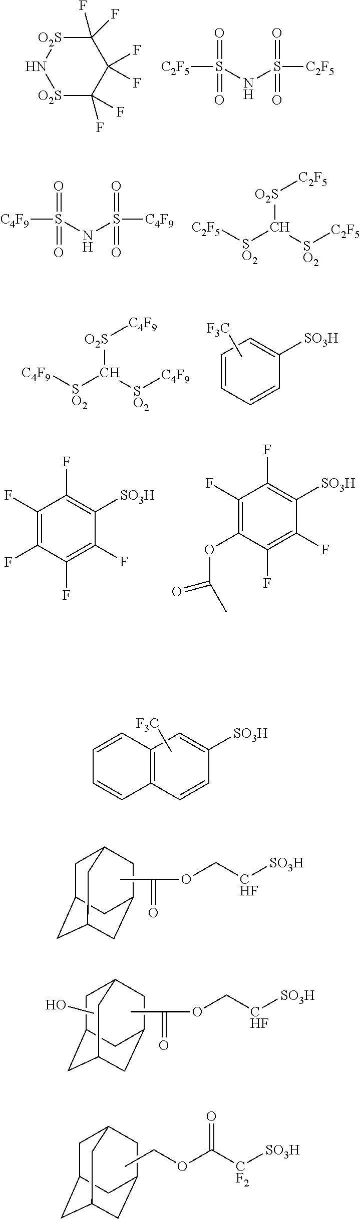

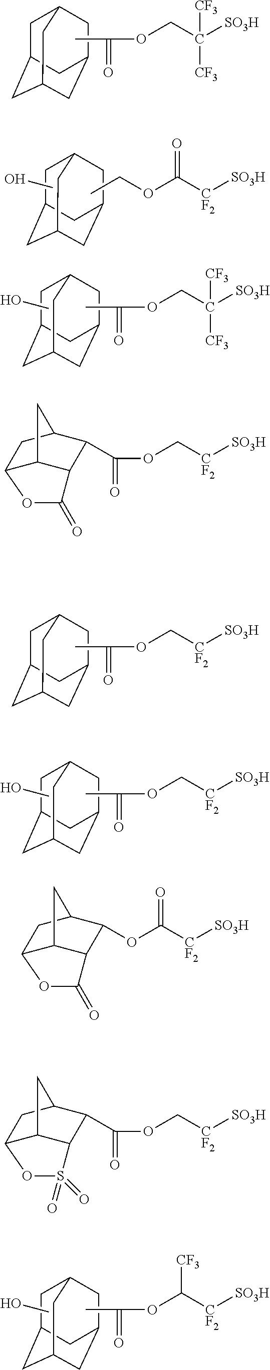

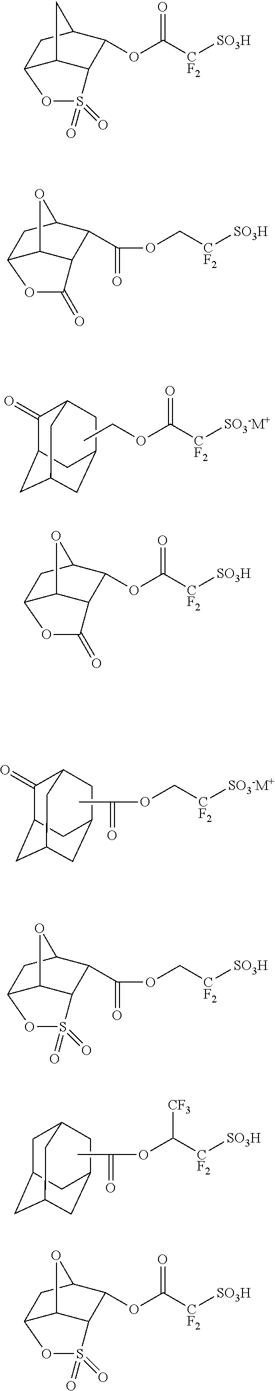

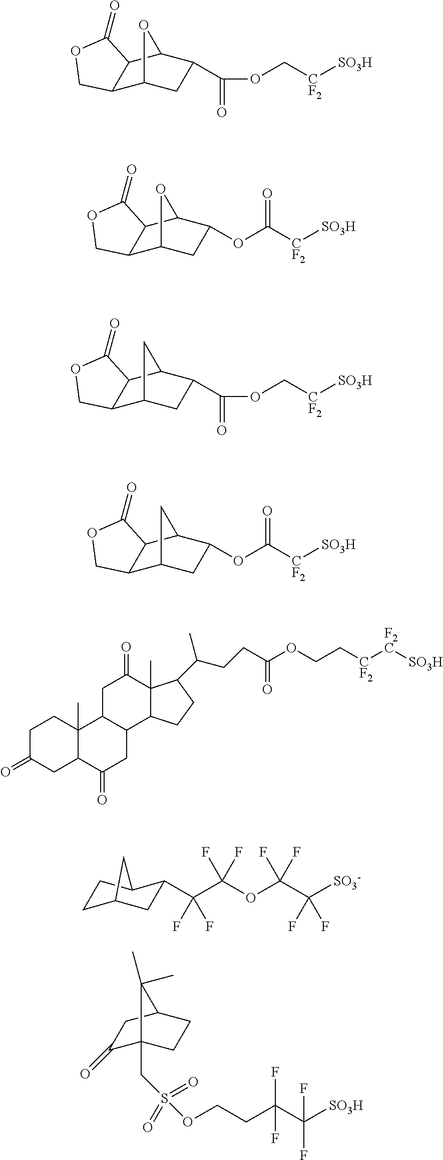

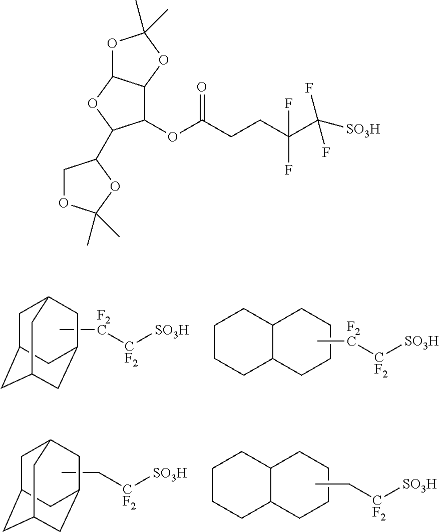

Suitable TAGs include those capable of generating a non-polymeric acid as described above. The TAG can be non-ionic or ionic. Suitable nonionic thermal acid generators include, for example, cyclohexyl trifluoromethyl sulfonate, methyl trifluoromethyl sulfonate, cyclohexyl p-toluenesulfonate, methyl p-toluenesulfonate, cyclohexyl 2,4,6-triisopropylbenzene sulfonate, nitrobenzyl esters, benzoin tosylate, 2-nitrobenzyl tosylate, tris(2,3-dibromopropyl)-1,3,5-triazine-2,4,6-trione, alkyl esters of organic sulfonic acids, p-toluenesulfonic acid, dodecylbenzenesulfonic acid, oxalic acid, phthalic acid, phosphoric acid, camphorsulfonic acid, 2,4,6-trimethylbenzene sulfonic acid, triisopropylnaphthalene sulfonic acid, 5-nitro-o-toluene sulfonic acid, 5-sulfosalicylic acid, 2,5-dimethylbenzene sulfonic acid, 2-nitrobenzene sulfonic acid, 3-chlorobenzene sulfonic acid, 3-bromobenzene sulfonic acid, 2-fluorocaprylnaphthalene sulfonic acid, dodecylbenzene sulfonic acid, 1-naphthol-5-sulfonic acid, 2-methoxy-4-hydroxy-5-benzoyl-benzene sulfonic acid, and their salts, and combinations thereof. Suitable ionic thermal acid generators include, for example, dodecylbenzenesulfonic acid triethylamine salts, dodecylbenzenedisulfonic acid triethylamine salts, p-toluene sulfonic acid-ammonium salts, p-toluene sulfonic acid-pyridinium salts, sulfonate salts, such as carbocyclic aryl and heteroaryl sulfonate salts, aliphatic sulfonate salts, and benzenesulfonate salts. Compounds that generate a sulfonic acid upon activation are generally suitable. Preferred thermal acid generators include p-toluenesulfonic acid ammonium salts, and heteroaryl sulfonate salts.

Preferably, the TAG is ionic with a reaction scheme for generation of a sulfonic acid as shown below:

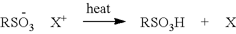

wherein RSO₃⁻ is the TAG anion and X⁺ is the TAG cation, preferably an organic cation. The cation can be a nitrogen-containing cation of the general formula (I):

(BH)⁺ (I)

which is the monoprotonated form of a nitrogen-containing base B. Suitable nitrogen-containing bases B include, for example: optionally substituted amines such as ammonia, difluoromethylammonia, C1-20 alkyl amines, and C3-30 aryl amines, for example, nitrogen-containing heteroaromatic bases such as pyridine or substituted pyridine (e.g., 3-fluoropyridine), pyrimidine and pyrazine; nitrogen-containing heterocyclic groups, for example, oxazole, oxazoline, or thiazoline. The foregoing nitrogen-containing bases B can be optionally substituted, for example, with one or more group chosen from alkyl, aryl, halogen atom (preferably fluorine), cyano, nitro and alkoxy. Of these, base B is preferably a heteroaromatic base.

Base B typically has a pKa from 0 to 5.0, or between 0 and 4.0, or between 0 and 3.0, or between 1.0 and 3.0. As used herein, the term “pKa” is used in accordance with its art-recognized meaning, that is, pKa is the negative log (to the base 10) of the dissociation constant of the conjugate acid (BH)⁺ of the basic moiety (B) in aqueous solution at about room temperature. In certain embodiments, base B has a boiling point less than about 170° C., or less than about 160° C., 150° C., 140° C., 130° C., 120° C., 110° C., 100° C. or 90° C.

Exemplary suitable nitrogen-containing cations (BH)⁺ include NH₄⁺, CF₂HNH₂⁺, CF₃CH₂NH₃⁺, (CH₃)₃NH⁺, (C₂H₅)₃NH⁺, (CH₃)₂(C₂H₅)NH⁺ and the following:

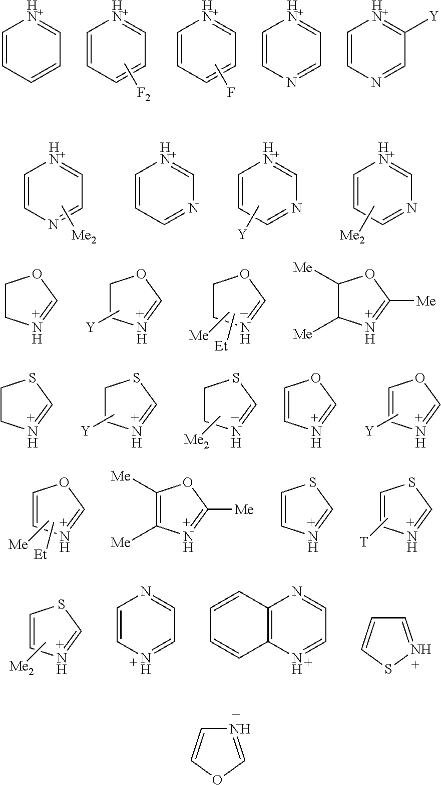

in which Y is alkyl, preferably, methyl or ethyl.

In particular embodiments, the solubility-shifting agent may be an acid such as trifluoromethanesulfonic acid, perfluoro-1-butanesulfonic acid, p-toluenesulfonic acid, 4-dodecylbenzenesulfonic acid, 2,4-dinitrobenzenesulfonic acid, and 2-trifluoromethylbenzenesulfonic acid; an acid generator such as triphenylsulfonium antimonate, pyridinium perfluorobutane sulfonate, 3-fluoropyridinium perfluorobutanesulfonate, 4-t-butylphenyltetramethylenesulfonium perfluoro-1-butanesulfonate, 2-4-t-butylphenyltetramethylenesulfonium trifluoromethylbenzenesulfonate, and 4-t-butylphenyltetramethylenesulfonium 4,4,5,5,6,6-hexafluorodihydro-4H-1,3,2-dithiazine 1,1,3,3-tetraoxide; or a combination thereof.

Alternatively, when the first photoresist is an NTD photoresist, the solubility-shifting agent may include a base or base generator. In such embodiments, suitable solubility-shifting agents include, but are not limited to, hydroxides, carboxylates, amines, imines, amides, and mixtures thereof. Specific examples of bases include ammonium carbonate, ammonium hydroxide, ammonium hydrogen phosphate, ammonium phosphate, tetramethylammonium carbonate, tetramethylammonium hydroxide, tetramethylammonium hydrogen phosphate, tetramethylammonium phosphate, tetraethylammonium carbonate, tetraethylammonium hydroxide, tetraethylammonium hydrogen phosphate, tetraethylammonium phosphate, and combinations thereof. Amines include aliphatic amines, cycloaliphatic amines, aromatic amines and heterocyclic amines. The amine may be a primary, secondary or tertiary amine. The amine may be a monoamine, diamine or polyamine. Suitable amines may include C1-30 organic amines, imines, or amides, or may be a C1-30 quaternary ammonium salt of a strong base (e.g., a hydroxide or alkoxide) or a weak base (e.g., a carboxylate). Exemplary bases include amines such as tripropylamine, dodecylamine, tris(2-hydroxypropyl)amine, tetrakis(2-hydroxypropyl)ethylenediamine; aryl amines such as diphenylamine, triphenylamine, aminophenol, and 2-(4-aminophenyl)-2-(4-hydroxyphenyl) propane, Troger's base, a hindered amine such as diazabicycloundecene (DBU) or diazabicyclononene (DBN), amides like tert-butyl 1,3-dihydroxy-2-(hydroxymethyl) propan-2-ylcarbamate and tert-butyl 4-hydroxypiperidine-1-carboxylateor; or ionic quenchers including quaternary alkyl ammonium salts such as tetrabutylammonium hydroxide (TBAH) or tetrabutylammonium lactate. In another embodiment, the amine is a hydroxyamine. Examples of hydroxyamines include hydroxyamines having one or more hydroxyalkyl groups each having 1 to about 8 carbon atoms, and preferably 1 to about 5 carbon atoms such as hydroxymethyl, hydroxyethyl and hydroxybutyl groups. Specific examples of hydroxyamines include mono-, di- and tri-ethanolamine, 3-amino-1-propanol, 2-amino-2-methyl-1-propanol, 2-amino-2-ethyl-1,3-propanediol, tris(hydroxymethyl) aminomethane, N-methylethanolamine, 2-diethylamino-2-methyl-1-propanol and triethanolamine.

Suitable base generators may be thermal base generators. A thermal base generator forms a base upon heating above a first temperature, typically about 140° C. or higher. The thermal base generator may include a functional group such as an amide, sulfonamide, imide, imine, O-acyl oxime, benzoyloxycarbonyl derivative, quarternary ammonium salt, nifedipine, carbamate, and combinations thereof. Exemplary thermal base generators include o-{(.beta.-(dimethylamino)ethyl)aminocarbonyl}benzoic acid, o-{(.gamma.-(dimethylamino) propyl)aminocarbonyl}benzoic acid, 2,5-bis {(.beta.-(dimethylamino)ethyl)aminocarbonyl}terephthalic acid, 2,5-bis {(.gamma.-(dimethylamino) propyl)aminocarbonyl}terephthalic acid, 2,4-bis {(.beta.-(dimethylamino)ethyl)aminocarbonyl}isophthalic acid, 2,4-bis {(.gamma.-(dimethylamino) propyl)aminocarbonyl}isophthalic acid, and combinations thereof.

In one or more embodiments, the solubility-shifting agent includes a solvent. As described above, in some embodiments the solubility-shifting agent is absorbed into the first relief pattern. Accordingly, the solvent may be any suitable solvent that may facilitate absorption into the first relief pattern, provided that it does not dissolve the first photoresist. The solvent is typically chosen from water, organic solvents and mixtures thereof. In some embodiments, the solvent may include an organic-based solvent system comprising one or more organic solvents. The term “organic-based” means that the solvent system includes greater than 50 wt % organic solvent based on total solvents of the solubility-shifting agent composition, more typically greater than 90 wt %, greater than 95 wt %, greater than 99 wt % or 100 wt % organic solvents, based on total solvents of the solubility-shifting agent compositions. The solvent component is typically present in an amount of from 90 to 99 wt % based on the solubility-shifting agent composition.

Suitable organic solvents for the solubility-shifting agent composition include, for example: alkyl esters such as alkyl propionates such as n-butyl propionate, n-pentyl propionate, n-hexyl propionate and n-heptyl propionate, and alkyl butyrates such as n-butyl butyrate, isobutyl butyrate and isobutyl isobutyrate; ketones such as 2,5-dimethyl-4-hexanone and 2,6-dimethyl-4-heptanone; aliphatic hydrocarbons such as n-heptane, n-nonane, n-octane, n-decane, 2-methylheptane, 3-methylheptane, 3,3-dimethylhexane and 2,3,4-trimethylpentane, and fluorinated aliphatic hydrocarbons such as perfluoroheptane; alcohols such as straight, branched or cyclic C₄-C₉ monohydric alcohol such as 1-butanol, 2-butanol, isobutyl alcohol, tert-butyl alcohol, 3-methyl-1-butanol, 1-pentanol, 2-pentanol, 4-methyl-2-pentanol, 1-hexanol, 1-heptanol, 1-octanol, 2-hexanol, 2-heptanol, 2-octanol, 3-hexanol, 3-heptanol, 3-octanol and 4-octanol; 2,2,3,3,4,4-hexafluoro-1-butanol, 2,2,3,3,4,4,5,5-octafluoro-1-pentanol and 2,2,3,3,4,4,5,5,6,6-decafluoro-1-hexanol, and C₅-C₉ fluorinated diols such as 2,2,3,3,4,4-hexafluoro-1,5-pentanediol, 2,2,3,3,4,4,5,5-octafluoro-1,6-hexanediol and 2,2,3,3,4,4,5,5,6,6,7,7-dodecafluoro-1,8-octanediol; ethers such as isopentyl ether and dipropylene glycol monomethyl ether; and mixtures containing one or more of these solvents.

The solvent included in the absorbed material may depend on the composition and tone of the first resist. When the first resist is formed from a (meth)acrylate polymer, as is typical for ArF resists, and the resist is developed as a PTD resist, the solvent system preferably comprises one or more polar organic solvents. For example, a solubility-shifting agent meant to be absorbed into a PTD first resist may include a polar solvent such as methyl isobutyl carbinol (MIBC). The solubility-shifting agent may also include aliphatic hydrocarbons, esters, and ethers as cosolvents such as, for example, decane, isobutyl isobutyrate, isoamyl ether, and combinations thereof. In particular embodiments, the solvent includes MIBC and a cosolvent. In such embodiments, the MIBC may be included in the solvent in an amount ranging from 60 to 99%, based on the total volume of solvent. Accordingly, the cosolvent may be included in amount ranging from 1 to 40%, based on the total volume of solvent.

When the first resist is formed from a vinyl aromatic-based polymer, as is typical for KrF and EUV photoresists, and the resist is developed as a PTD resist, the solvent system preferably comprises one or more non-polar organic solvents. The term “non-polar organic-based” means that the solvent system includes greater than 50 wt % of combined non-polar organic solvents based on total solvents of the solubility-shifting agent composition, more typically greater than 70 wt %, greater than 85 wt % or 100 wt %, combined non-polar organic solvents, based on total solvents of the solubility-shifting agent composition. The non-polar organic solvents are typically present in the solvent system in a combined amount of from 70 to 98 wt %, preferably 80 to 95 wt %, more preferably from 85 to 98 wt %, based on the solvent system.

Suitable non-polar solvents include, for example, ethers, hydrocarbons, and combinations thereof, with ethers being preferred. Suitable ether solvents include, for example, alkyl monoethers and aromatic monoethers, particularly preferred of which are those having a total carbon number of from 6 to 16. Suitable alkyl monoethers include, for example, 1,4-cineole, 1,8-cineole, pinene oxide, di-n-propyl ether, diisopropyl ether, di-n-butyl ether, di-n-pentyl ether, diisoamyl ether, dihexyl ether, diheptyl ether, and dioctyl ether, with diisoamyl ether being preferred. Suitable aromatic monoethers include, for example, anisole, ethylbenzyl ether, diphenyl ether, dibenzyl ether and phenetole, with anisole being preferred. Suitable aliphatic hydrocarbons include, for example, n-heptane, 2-methylheptane, 3-methylheptane, 3,3-dimethylhexane, 2,3,4-trimethylpentane, n-octane, n-nonane, n-decane, and fluorinated compounds such as perfluoroheptane. Suitable aromatic hydrocarbons include, for example, benzene, toluene, and xylene.

In some embodiments, the solvent system further includes one or more alcohol and/or ester solvents. For certain compositions, an alcohol and/or ester solvent may provide enhanced solubility with respect to the solid components of the composition. Suitable alcohol solvents include, for example: straight, branched or cyclic C₄₋₉ monohydric alcohol such as 1-butanol, 2-butanol, isobutyl alcohol, tert-butyl alcohol, 3-methyl-1-butanol, 1-pentanol, 2-pentanol, 4-methyl-2-pentanol, 1-hexanol, 1-heptanol, 1-octanol, 2-hexanol, 2-heptanol, 2-octanol, 3-hexanol, 3-heptanol, 3-octanol, 4-octanol, 2,2,3,3,4,4-hexafluoro-1-butanol, 2,2,3,3,4,4,5,5-octafluoro-1-pentanol, and 2,2,3,3,4,4,5,5,6,6-decafluoro-1-hexanol; and C5-9 fluorinated diols such as 2,2,3,3,4,4-hexafluoro-1,5-pentanediol, 2,2,3,3,4,4,5,5-octafluoro-1,6-hexanediol, and 2,2,3,3,4,4,5,5,6,6,7,7-dodecafluoro-1,8-octanediol. The alcohol solvent is preferably a C₄₋₉ monohydric alcohol, with 4-methyl-2-pentanol being preferred. Suitable ester solvents include, for example, alkyl esters having a total carbon number of from 4 to 10, for example, alkyl propionates such as n-butyl propionate, n-pentyl propionate, n-hexyl propionate, and n-heptyl propionate, and alkyl butyrates such as n-butyl butyrate, isobutyl butyrate, and isobutyl isobutyrate. The one or more alcohol and/or ester solvents if used in the solvent system are typically present in a combined amount of from 2 to 50 wt %, more typically in an amount of from 2 to 30 wt %, based on the solvent system.

The solvent system can also include one or more additional solvents chosen, for example, from one or more of: ketones such as 2,5-dimethyl-4-hexanone and 2,6-dimethyl-4-heptanone; and polyethers such as dipropylene glycol monomethyl ether and tripropylene glycol monomethyl ether. Such additional solvents, if used, are typically present in a combined amount of from 1 to 20 wt % based on the solvent system.

When the first resist is formed from a vinyl aromatic-based polymer, a particularly preferred organic-based solvent system includes one or more monoether solvents in a combined amount of from 70 to 98 wt % based on the solvent system, and one or more alcohol and/or ester solvents in a combined amount of from 2 to 30 wt % based on the solvent system. The solvent system is typically present in the overcoat composition in an amount of from 90 to 99 wt %, preferably from 95 to 99 wt %, based on the overcoat composition.

In embodiments in which the first resist is a NTD resist, suitable organic solvents include, but are not limit to, n-butyl acetate, 2-heptanone, propylene glycol methyl ether, propylene glycol methyl ether acetate, and combinations thereof.

In some embodiments, the solubility-shifting agent is coated over the first relief pattern. To properly coat the first relief pattern, the solubility-shifting agent may include a matrix polymer. Any matrix polymer commonly used in the art may be included in the solubility-shifting material. The matrix polymer should have good solubility in a solvent that does not dissolve the first resist. The matrix polymer can be formed from one or more monomers chosen, for example, from those having an ethylenically unsaturated polymerizable double bond, such as: (meth)acrylate monomers such as isopropyl (meth)acrylate and n-butyl (meth)acrylate; (meth)acrylic acid; vinyl aromatic monomers such as styrene, hydroxystyrene, vinyl naphthalene and acenaphthylene; vinyl alcohol; vinyl chloride; vinyl pyrrolidone; vinyl pyridine; vinyl amine; vinyl acetal; maleic anhydride; maleimides; norbornenes; and combinations thereof.

In some embodiments, the polymer contains one or more functional groups chosen, for example, from hydroxy, acid groups such as carboxyl, sulfonic acid and sulfonamide, silanol, fluoroalcohol such as hexafluoroisopropyl alcohol [—C(CF₃)₂OH], anhydrates, lactones, esters, ethers, allylamine, pyrrolidones and combinations thereof. The polymer can be a homopolymer or a copolymer having a plurality of distinct repeat units, for example, two, three, four or more distinct repeat units. In one aspect, the repeat units of the polymer are all formed from (meth)acrylate monomers, are all formed from (vinyl) aromatic monomers or are all formed from (meth)acrylate monomers and (vinyl) aromatic monomers. When the polymer includes more than one type of repeat unit, it typically takes the form of a random copolymer.

In particular embodiments, the matrix polymer may be a t-butyl acrylate (TBA)/p-hydroxystyrene (PHS) copolymer, a butyl acrylate (BA)/PHS copolymer, a TBA/methacrylic acid (MAA) copolymer, a BA/MAA copolymer, a PHS/methacrylate (MA) copolymer, and combinations thereof.

The solubility-shifting agent compositions typically include a single polymer but can optionally include one or more additional polymers. The content of the polymer in the composition will depend, for example, on the target thickness of the layer, with a higher polymer content being used when thicker layer is desired. The polymer is typically present in the pattern solubility-shifting agent composition in an amount of from 80 to 99.9 wt %, more typically from 90 to 99 wt %, or 95 to 99 wt %, based on total solids of the solubility-shifting agent composition. The weight average molecular weight (Mw) of the polymer is typically less than 400,000, preferably from 3000 to 50,000, more preferably from 3000 to 25,000, as measured by GPC versus polystyrene standards. Typically, the polymer will have a polydispersity index (PDI=Mw/Mn) of 3 or less, preferably 2 or less, as measured by GPC versus polystyrene standards.

Suitable polymers for use in the solubility-shifting agent compositions are commercially available and/or can readily be made by persons skilled in the art. For example, the polymer may be synthesized by dissolving selected monomers corresponding to units of the polymer in an organic solvent, adding a radical polymerization initiator thereto, and effecting heat polymerization to form the polymer. Examples of suitable organic solvents that can be used for polymerization of the polymer include, for example, toluene, benzene, tetrahydrofuran, diethyl ether, dioxane, ethyl lactate and methyl isobutyl carbinol. Suitable polymerization initiators include, for example, 2,2′-azobisisobutyronitrile (AIBN), 2,2′-azobis(2,4-dimethylvaleronitrile), dimethyl 2,2-azobis(2-methylpropionate), benzoyl peroxide and lauroyl peroxide.

Solubility-shifting agents including a matrix polymer may be coated over the first relief pattern according to methods known in the art. Typically, a solubility-shifting agent that includes a matrix polymer may coated over the first relief pattern by spin coating. The solids content of the solubility-agent may be tailored to provide a film of a desired thickness of the solubility-shifting agent over the first relief pattern. For example, the solids content of the solubility-shifting agent solution can be adjusted to provide a desired film thickness based upon the specific coating equipment utilized, the viscosity of the solution, the speed of the coating tool and the amount of time allowed for spinning. A typical thickness for the composition is from about 200 Å to about 1500 Å.

In one or more embodiments, a solubility-shifting agent includes an active material (i.e., an acid, acid generator, base, or base generator), a solvent, and a matrix polymer as previously described. A typical formulation for such solubility-shifting agent may include about 1 to 10 wt % solids and 90 to 99 wt % solvent, based on the total weight of the solubility shifting agent, where the solids include the active material and the matrix polymer. Within the solids content, the active material may be included in an amount ranging from about 1 to about 5 wt %.

The solubility-shifting agent may include additives having various purposes, depending on the particular chemistry being used. In some embodiments, a surfactant may be included in the solubility-shifting agent. A surfactant may be included in the solubility-shifting agent to help with coating quality, especially when needing to fill thin gaps between features of the first photoresist. Any suitable surfactant known in the art may be included in the solubility-shifting agent.

As noted above, in one or more embodiments, the solubility-shifting agent is absorbed into the first relief pattern. Absorption of the solubility-shifting agent into the first relief pattern may be achieved by performing a thermal pretreatment such as a bake. The bake may be a soft bake. The temperature and time of the soft bake may depend on the identity of the first resist, and the desired amount of diffusion of the solubility-shifting agent into the first resist. Typically, a soft bake may be performed for about 30 seconds to about 90 seconds at a temperature ranging from about 50 to about 150° C.

After diffusion into the first resist, a coating layer that does not include any active solubility-shifting material, may remain on the first resist. In one or more embodiments, the coating layer may be removed by a rinse. The rinse may be accomplished by rinsing the coated substrate with a solvent that dissolves the coating layer but does not dissolve the first resist. The rinse may be carried out using any suitable method, for example, by dipping a substrate in a bath filled with the solvent for a fixed time (dip method), by raising the solvent on a substrate surface by the effect of a surface tension and keeping it still for a fixed time, thereby dissolving the coating layer (puddle method), by spraying the solvent on a substrate surface (spray method), or by continuously ejecting the solvent on a substrate rotating at a constant speed while scanning the solvent ejecting nozzle at a constant rate (dynamic dispense method).

At block 106 of method 100, a second resist is deposited on the substrate. A coated substrate layered with a first relief pattern 204, a solubility-shifting agent 205, and a second resist 206 is shown in FIG. 2C. The second resist may be deposited on the substrate such that it fills gaps of the first relief pattern and is in contact with the first relief pattern or the solubility-shifting agent. In one or more embodiments, the second resist completely covers the substrate, the first relief pattern, and the solubility-shifting agent. The second resist may be deposited on the substrate according to any suitable method known in the art such as, for example, spin-on deposition or vapor-phase treatment.

In one or more embodiments, the second resist includes a polymer. Suitable polymers may be as previously described with respect to the polymer defined as the first resist polymer and/or the matrix polymer. In particular embodiments, suitable polymers may be made from monomers including p-hydroxystyrene, styrene, t-butyl acrylate, and combinations thereof. In particular embodiments, the polymer is made from all three of p-hydroxystyrene, styrene, and t-butylacrylate. Such polymer may be prepared from a polymerization reaction including from about 50 to 80% p-hydroxystyrene, from about 10 to 30% styrene, and from about 10 to 30% t-butylacrylate. For example, a polymerization reaction to produce a polymer included in the second resist may include p-hydroxystyrene in an amount ranging from a lower limit of one of 50, 55, 60, and 65% to an upper limit of one of 65, 70, 75, and 80%, where any lower limit may be paired with any mathematically compatible upper limit, and styrene and t-butyl acrylate in individual amounts ranging from a lower limit of one of 10, 12, 14, 16, 18, and 20% to an upper limit of one of 20, 22, 24, 26, 28, and 30%, where any lower limit may be paired with any mathematically compatible upper limit.

The polymer included in the second resist may have a weight average molecular weight (Mw) ranging from 1 to 100 kg/mol. For example, in one or more embodiments, the second resist may include a polymer having a Mw ranging from a lower limit of one of 1, 2, 5, 10,15, 20, and 25 kg/mol to an upper limit of one of 25, 50, 75, 80, 90, and 100 kg/mol, where any lower limit may be paired with any mathematically compatible upper limit. A polymer having such Mw may exhibit desired solubility characteristics, such as, in particular, the dissolution rate.

In one or more embodiments, the second resist includes a photoacid generator. The photoacid generator may be as previously described with respect to the photoacid generator included in the first resist.

In one or more embodiments, the second resist includes a solvent. The solvent may be as previously described with respect to the solvent included in the solubility-shifting agent. In particular embodiments, the solvent in the second resist is the same as the solvent in the solubility-shifting agent.

The second resist may include additives having various purposes, depending on the particular chemistry being used. In some embodiments, a quencher is included in the second resist. A quencher may be included in the second resist to help control the diffusion of the active material in the solubility-shifting agent. Suitable quenchers include any of the bases previously listed with reference to the solubility-shifting material.

The second resist may be a PTD or NTD resist. Both PTD and NTD rests may include a polymer and a solvent as described above. In embodiments in which the second resist is an NTD resist, it may also include an acid or acid generator. The acid or acid generator is as previously described with reference to the solubility-shifting material.

At block 108 of method 100 the solubility-shifting agent is diffused into the second resist. In one or more embodiments, diffusion of the solubility-shifting agent into the second resist is achieved by performing a bake. The bake may be carried out with a hotplate or oven. The temperature and time of the bake may depend on the identity of the second resist, and the desired amount of diffusion of the solubility-shifting agent into the second resist. Suitable conditions for the bake may include a temperature ranging from 50 to 160° C., and a time ranging from about 30 to 90 seconds. In one or more embodiments, after the bake a solubility-shifted region may be present around the edges of the second resist. The amount of diffusion of the solubility-shifting agent may correspond to the thickness of the solubility-shifted region. In some embodiments, the solubility-shifted region extends into the second resist such that it has a thickness of about 5 to about 60 nm. For example, the thickness of the solubility-shifted region may range from a lower limit of one of 5, 10, 15, 20, and 25 nm to an upper limit of one of 40, 45, 50, 55, and 60 nm, where any lower limit may be paired with any mathematically compatible upper limit. In one or more embodiments, the thickness of the solubility-shifted region may correspond to the desired width of the line that is to be cut into the substrate.

A coated substrate including a solubility-shifted region is shown in FIG. 2D. As shown in FIG. 2D, the coated substrate includes a substrate layer 202. The substrate is as previously described. The first relief pattern 204, comprised of the first photoresist 203, is on top of the substrate 202. The first relief pattern 204 is coated with the solubility shifting agent. The second resist 208 is coated over the first relief pattern and the substrate. In one or more embodiments, the second resist 208 completely covers the substrate 202 and the first relief pattern 204. A solubility-shifted region 206 of the second resist is shown bordering the first relief pattern.

The solubility-shifted region may have a different solubility than the region of the second resist that was unexposed to the solubility-shifting agent. As such, the solubility-shifted region and the unexposed region of the second resist may be soluble in different resist developers.

At block 110 of method 100, the deposited layer of second resist may be developed using a specific developer such that either the solubility-shifted region or the unexposed region of the second resist remains. In one or more embodiments, the solubility-shifted region of the second resist is developed by first being exposed to actinic radiation, and then being exposed to a specific developer. In other embodiments, the solubility-shifted region of the second resist is only exposed to the specific developer. The specific developer may depend on the tone of the second resist. For example, if the second resist is a positive tone developed photoresist, the specific developer may be a base such as tetramethylammonium hydroxide. On the other hand, if the second resist is a negative tone developed resist, the specific developer may be a nonpolar organic solvent, such as n-butyl acetate or 2-heptanone.

As described previously, the thickness of the solubility-shifted region may correspond to the desired width of the line to be cut into the substrate. FIG. 2E shows a coated substrate that has been developed according to embodiments of the present disclosure. In one or more embodiments, the second resist 208 is developed so as to dissolve the solubility-shifted region, which is between the first relief pattern and the second resist. Accordingly, dissolution of the solubility-shifted region may result in the formation of trenches 210 between the first relief pattern 204 and the second resist 208 in which the substrate 202 is exposed. Thus, method 100, referring back to FIG. 1, includes etching the exposed portions of the substrate using the first relief pattern and the second resist as a combined etch mask. Such method may provide narrow line cuts on the substrate. The etch process may be an isotropic or anisotropic etch process, using any suitable dry etchant, such as CF, O, HBr, or F. In one embodiment, the etchant can be a dry etchant such as CF, O, HBr, and F.

Method 100 represents one possible embodiment and is not intended to limit the scope of the present invention. As will be appreciated by one of ordinary skill in the art, the present invention may encompass various alternative methods, such as, for example, methods in which the solubility-shifting agent is diffused into, and changes the solubility of a region of, the first resist rather than the second resist. In such alternate embodiments, the components and techniques used in the methods may be as previously described with reference to method 100.

In one or more embodiments, the solubility-shifting agent is diffused into the first resist. In such embodiments, a method may include initially forming a first relief pattern of a first resist and then coating the first resist with a solubility-shifting agent. At this point, the solubility-shifting agent may be diffused into the first resist a predetermined distance to provide a solubility-shifted region of the first resist. FIG. 2F shows a coated substrate including a first resist 203 that has a solubility-shifted region 206. While diffusion of the solubility-shifting agent may occur at a different point in such method and into a different component, diffusion of the solubility-shifting agent may be carried out as described above in method 100. After the solubility-shifting agent is diffused into the first resist, the second resist may be deposited on the substrate. FIG. 2G shows a first resist 203 including a solubility-shifted region 206 on a substrate coated with a second resist 208. Then, the substrate may be developed and etched as described with reference to method 100, where the solubility-shifted region of the first resist is soluble in the specific developer.

In one or more embodiments, methods may include forming multiple narrow line cuts on a substrate. Such methods may include components such as a first resist, a solubility-shifting agent, and a second resist and process steps such as coating, diffusing and developing, among others. As will be appreciated by one of ordinary skill in the art, such components and process steps may be as previously described with respect to method 100.

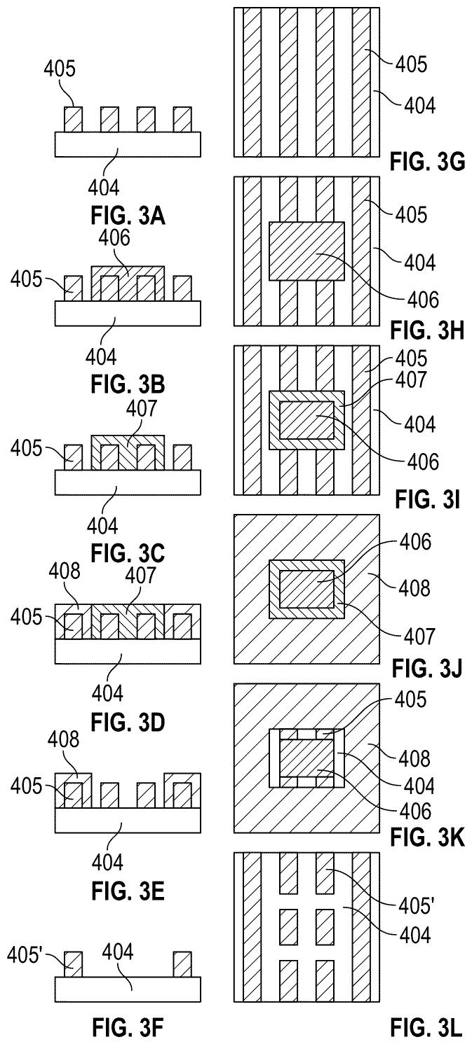

FIGS. 3A-L, on the other hand, shows a schematic illustration of an exemplary method for cutting multiple narrow lines using base technology. In FIGS. 3A and 3G, a pattern of lines 405 is formed on a substrate 404. The lines may be formed of a hardmask material and may be formed by methods generally known in the art. art. Suitable hardmask materials are known in the art and include, for example, silicon oxide, silicon nitride, silicon oxynitride, tungsten, titanium, titanium nitride, titanium oxide, zirconium oxide, aluminum oxide, aluminum oxynitride, hafnium oxide and SOC. Then, a lithography step is performed to define a cut pattern 406 using a first resist, shown in FIGS. 3B and 3H. The photoresist cut pattern 406 is then treated with a solubility-shifting agent which diffuses a predetermined distance into the first resist to provide a solubility-shifted region 407, shown in FIGS. 3C and 3I.

A second resist 408 is then coated over the substrate in FIGS. 3D and 3J. Then, the substrate is developed to remove the solubility-shifted region 407, such that portions of the pattern of lines 405 of the hardmask and the substrate 404 are exposed in FIGS. 3E and 3K, and the exposed portions of the pattern of lines are etched to form a new pattern of modified lines 405′ in FIGS. 3F and 3L.

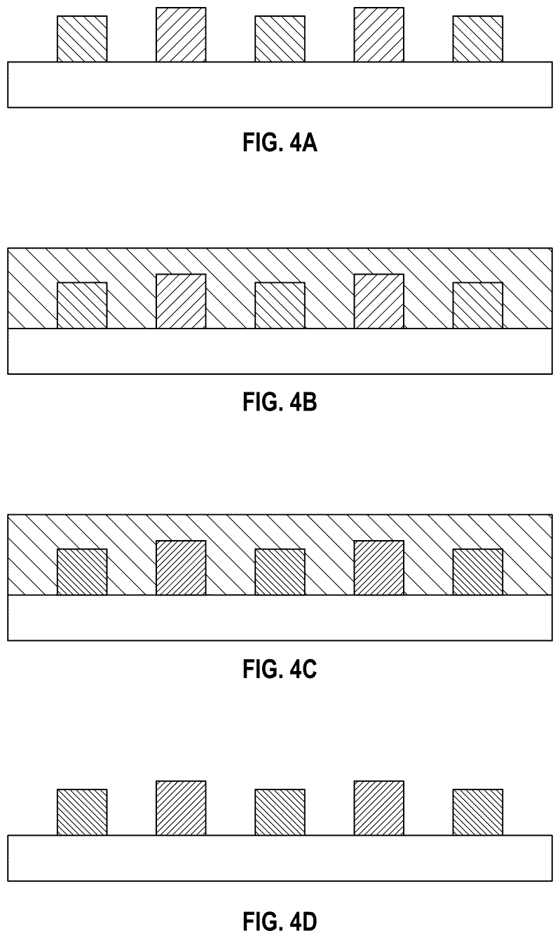

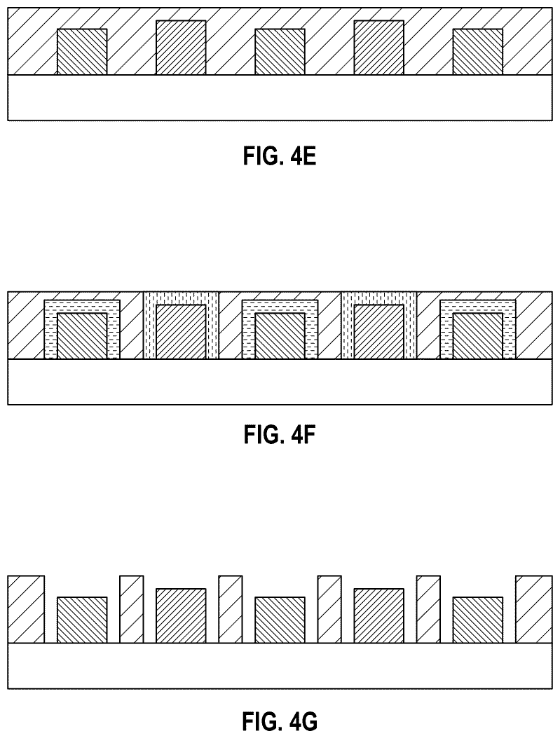

In one or more embodiments, an anti-spacer on anti-spacer process may be performed. In such processes, methods may carry out the steps of method 100 one or more times. For example, an anti-spacer on anti-spacer process is shown by schematic illustrations of a coated substrate at each step of such process, in FIGS. 4A-G. As shown by the coated substrate in FIG. 4A, an anti-spacer on anti-spacer process may initially include providing a series of anti-spacers on a substrate according to an anti-spacer process such as, for example, method 100. Then, a second solubility-shifting agent is coated on the anti-spacer pattern to provide the coated substrate in FIG. 4B. The second solubility-shifting agent may be as previously described with respect to the solubility-shifting agent in method 100. In FIG. 4C, the second solubility shifting is absorbed into the first and second resist that make up the anti-spacer pattern, and then the coating is removed to provide coated substrate in FIG. 4D. Then, FIG. 4E shows a coated substrate that includes a third resist that is coated over the anti-spacer pattern. The third resist may include a polymer as previously described. Then, the second solubility-shifting agent is diffused into the third resist. Diffusion of the third resist may be carried out by a bake, such as a soft bake described above. After diffusing the second solubility-shifting agent into the third resist, the third resist includes a solubility-shifted region around the edges of the first and second resists, as shown in FIG. 4F. Finally, the third resist is developed to such that the solubility-shifted region of the third resist dissolves, providing trenches where the substrate is exposed, as shown in FIG. 4G. Thus, FIGS. 4A-G demonstrate one embodiment of an anti-spacer on anti-spacer patterning process.

Alternatively, and as noted above with respect to a single anti-spacer patterning process, in an anti-spacer on anti-spacer process, the second solubility-shifting agent may be diffused into the first and second resist of the initial anti-spacer pattern rather than into the third resist. In such embodiments, the second solubility-shifting agent is deposited on the first and second resists that make up the anti-spacer pattern, and then diffused into the first and second resists such that solubility-shifted regions are provided around the edges of the pattern. Then, the third resist is layered over the anti-spacer pattern, and the method mat proceed as previously described. As will be appreciated by one of ordinary skill in the art, steps that are duplicated from method to method may be implemented as previously described.

In one or more embodiments, a thin line is cut according to a non-self aligned resist on litho technique. In such embodiments, lines may be defined lithographically, a substrate may be planarized, such that any gaps between the lithographically defined lines are filled with another material and the surface is flat, and a cut pattern may be defined by lithography. A narrow line may then be cut according to the method described above.

Thus, in one or more embodiments, to make effective semiconductor devices, different segments are isolated from each other-endless lines tend not to be useful. To segment lines, the lines can be initially generated as long lines, which typically benefits processing, and then cut into useful segments. In processing of semiconductor substrates, the creation of patterns on the layer of interest (patterning) can include one or more steps. First, some transfer layers are defined. Then a pattern is lithographically defined on the substrate. This is then transferred to the intermediate layer using directional etching.

In one or more embodiments, to perform a cut, a second litho layer (“cut mask”) is formed thereon. The cut width can have two functions. First, it sets an isolation distance between features, desirable for function and long-term reliability. Second, any additional area is “waste” that extends the features without adding benefit. A desired goal in forming a cut layer is to have a minimum width above the electrical breakdown limit (˜2-30 nm, depending on the features), and minimize extra extension.

In one or more embodiments, the width of the narrow line cut according to the present disclosure may be controlled by creating an etch mask using specific chemical techniques and principles. Thus, while the line may be placed lithographically, i.e., using lithographic techniques such as an etch mask, the disclosed method may be performed without lithographic scanners. Further, the line may be cut directly into the substrate, thus obviating the need for intermediate spacers or hardmask patterns and reducing costs.

What is claimed:

1. A method of patterning a substrate comprising:
providing a first relief pattern on a substrate, wherein the first relief pattern comprises a first resist;
coating the first relief pattern with a solubility-shifting agent;
depositing a second resist on the first relief pattern such that the second resist is in contact with the first relief pattern;
diffusing the solubility-shifting agent a predetermined distance into the second resist to provide a solubility-shifted region of the second resist, wherein the solubility-shifted region of the second resist borders the first relief pattern;
developing the second resist such that the solubility-shifted region is dissolved providing gaps between the first relief pattern and the second resist where a portion of the substrate is exposed; and
etching the substrate using the first relief pattern and the second resist as a combined etch mask.

2. The method of claim 1, wherein the first relief pattern comprises features separated by gaps between the features, wherein the features comprise the first resist.

3. The method of claim 1, wherein the second resist fills the gaps of the first relief pattern.

4. The method of claim 1, wherein the solubility-shifting agent is an acid or an acid generator.

5. The method of claim 1, wherein the solubility-shifting agent comprises a matrix polymer.

6. The method of claim 1, further comprising, directly after coating the first relief pattern with the solubility-shifting agent, diffusing the solubility-shifting agent into the first relief pattern.

7. The method of claim 1, wherein the first resist is a positive tone developed resist and the second resist comprises a polymer that is soluble in a polar solvent.

8. The method of claim 1, wherein the first resist is a negative tone developed resist and the second resist comprises a polymer that is soluble in a nonpolar organic solvent.

9. The method of claim 1, wherein the solubility-shifting agent comprises a solvent, wherein the first resist is insoluble in the solvent.

10. The method of claim 1, wherein providing the first relief pattern on the substrate comprises: forming a first pattern of lines on the substrate; depositing a layer of the first resist over the first pattern of lines; exposing the first resist to a pattern of actinic radiation and developing the first resist such that the first relief pattern is formed over the first pattern of lines.

11. A method of patterning a substrate comprising:
providing a first relief pattern on a substrate, wherein the first relief pattern comprises a first resist;
coating the first relief pattern with a solubility-shifting agent;
depositing a second resist on the first relief pattern such that the second resist is in contact with the first relief pattern;
diffusing the solubility-shifting agent a predetermined distance into the first resist to provide a solubility-shifted region of the first resist, wherein the solubility-shifted region of the first resist borders the second resist;
developing the first resist such that the solubility-shifted region is dissolved providing gaps between the first relief pattern and the second resist where a portion of the substrate is exposed; and
etching the substrate using the first relief pattern and the second resist as a combined etch mask.

12. The method of claim 11, wherein the first relief pattern comprises features separated by gaps between the features, wherein the features comprise the first resist.

13. The method of claim 11, wherein the second resist fills the gaps of the first relief pattern.

14. The method of claim 11, wherein the solubility-shifting agent is an acid or an acid generator.

15. The method of claim 11, wherein the solubility-shifting agent comprises a matrix polymer.

16. The method of claim 11, further comprising, directly after coating the first relief pattern with the solubility-shifting agent, diffusing the solubility-shifting agent into the first relief pattern.

17. The method of claim 11, wherein the first resist is a positive tone developed resist and the second resist comprises a polymer that is soluble in a polar solvent.

18. The method of claim 11, wherein the first resist is a negative tone developed resist and the second resist comprises a polymer that is soluble in a nonpolar organic solvent.

19. The method of claim 11, wherein the solubility-shifting agent comprises a solvent, wherein the first resist is insoluble in the solvent.

20. The method of claim 11, wherein providing the first relief pattern on the substrate comprises: forming a first pattern of lines on the substrate; depositing a layer of the first resist over the first pattern of lines; exposing the first resist to a pattern of actinic radiation and developing the first resist such that the first relief pattern is formed over the first pattern of lines.
